(19) United States
(12) Patent Application Publication
(10) Pub. No.: US 2013/0188317 A1
(43) Pub. Date: Jul. 25, 2013

(54) HEAT SINK AND ELECTRONIC DEVICE HAVING THE SAME

(71) Applicant: Hsin-Yin HO, Taipei City (TW)

(72) Inventor: Hsin-Yin HO, Taipei City (TW)

(21) Appl. No.: 13/354,661

(22) Filed: Jan. 20, 2012

(51) Int. Cl. H05K 7/20; F28F 7/00

(52) U.S. Cl. 361/710; 165/185

(57) ABSTRACT

A heat sink for an electronic device is made of thermally conductive materials and is formed by winding a rod into a helix so as to have a plurality of loops of progressively smaller diameters. With the above-mentioned structure, the heat sink can provide improved heat dissipation and air convection because of large surface area of the rod and no dead angle.

### BACKGROUND OF THE INVENTION

1. Field of the Invention

The present invention relates to a heat sink, and more particularly to a heat sink for an electronic device that has no dead angle and provides a large surface area for heat dissipation.

2. Description of the Prior Arts

Heat sinks are used to dissipate heat generated by electronic components of electronic devices, such as lighting devices, so as to prevent device failure and improve long term reliability.

For example, with reference to FIGS. 22 and 23, a conventional lighting device comprises a light source unit 30 mounted on a heat sink 40. The light source unit 30 includes a light-emitting diode (LED) 31 mounted on a carrier 32. The heat sink 40 includes a tubular member 41 and multiple fins 42. The tubular member 41 has a mounting board 411 to which the light source unit 30 is mounted and thermally coupled. The fins 42 extend radially outwardly from the tubular member 41. When the conventional lighting device is in use, the mounting board 411 absorbs heat from the light source unit 30 and transmits the heat to the fins 42 and then the fins 42 radiate the heat to the air.

However, a space between two adjacent fins 42 is small so that a dead angle 43 is formed between two adjacent fins 42 as shown in FIG. 23. The dead angle 43 does not allow air to flow therethrough and thus reduces air convection and heat dissipation. Besides, the heat sink 40 is formed by metal casting or die casting, which requires a long processing time and thus reduces production efficiency.

To overcome the shortcomings, the present invention provides a heat sink to mitigate or obviate the aforementioned problems.

### SUMMARY OF THE INVENTION

The main object of the present invention is to provide a heat sink for an electronic device. The heat sink is made of thermally conductive materials and is formed by winding a rod into a helix so as to have a plurality of loops of progressively smaller diameters. With the above-mentioned structure, the heat sink can provide improved heat dissipation and air convection because of large surface area of the rod and no dead angle.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of an electronic device in accordance with the present invention;

FIG. 2 is a side view of the electronic device in FIG. 1;

FIG. 3 is a top view of the electronic device in FIG. 1;

FIG. 4 is an enlarged perspective view of an electronic component in FIG. 1;

FIG. 5 is a perspective view of two heat sinks in accordance with the present invention;

FIG. 6 is an exploded perspective view of the two heat sinks in FIG. 5;

FIG. 7 is an enlarged perspective view of another electronic component in accordance with the present invention;

FIG. 8 is a top view of another electronic device in accordance with the present invention;

FIG. 9 is an enlarged side view in partial section of the electronic device in FIG. 8;

FIGS. 10 to 18 are enlarged perspective views of various embodiments of rods in accordance with the present invention;

FIGS. 19 to 21 are perspective views of different configurations of heat sinks in accordance with the present invention;

FIG. 22 is a perspective view of a conventional electronic device in accordance with the prior art; and

FIG. 23 is a side view in partial section of the conventional electronic device in FIG. 22.

### DETAILED DESCRIPTION OF THE PREFERRED EMBODIMENTS

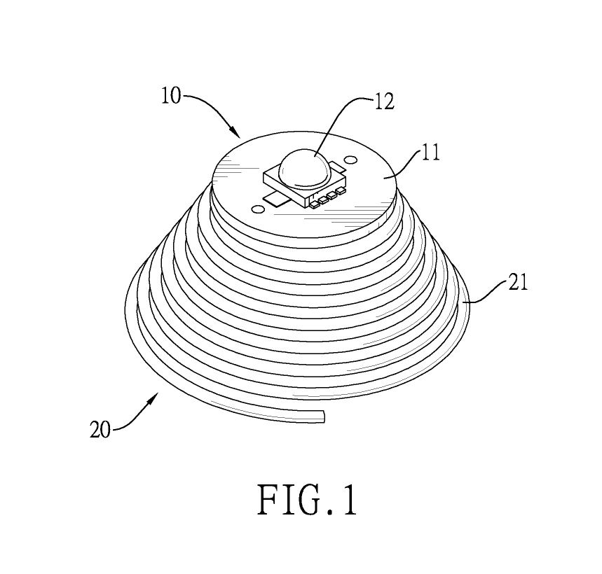

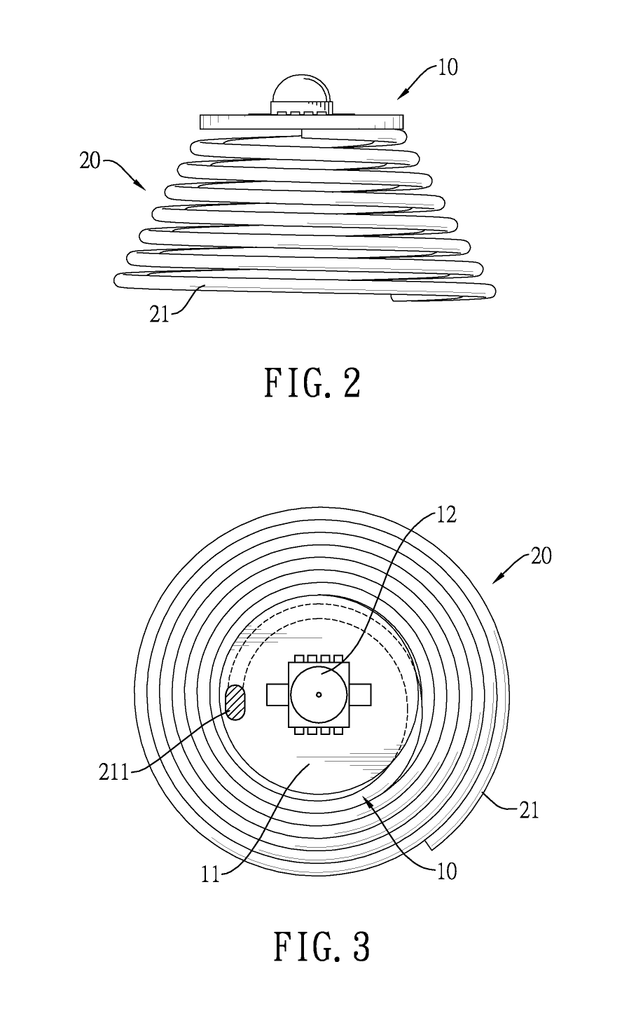

With reference to FIGS. 1 to 3, an electronic device in accordance with the present invention, for example, a lighting device, comprises an electronic component 10 and at least one heat sink 20.

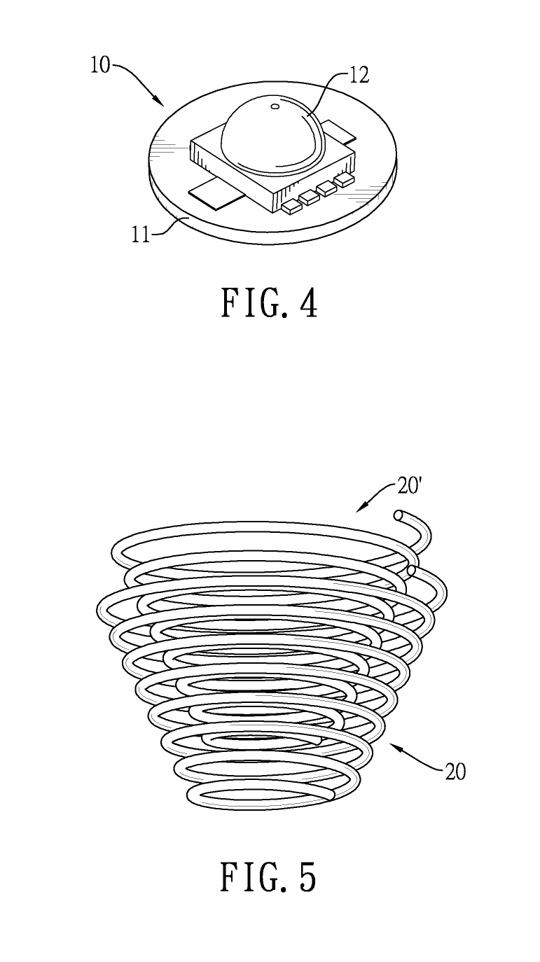

With reference to FIG. 4, the electronic component 10 includes a carrier 11 and a heat-generating element 12. The carrier 11 is a heat dissipating plate and has two side surfaces. The heat-generating element 12 is mounted on one of the side surfaces of the carrier 11.

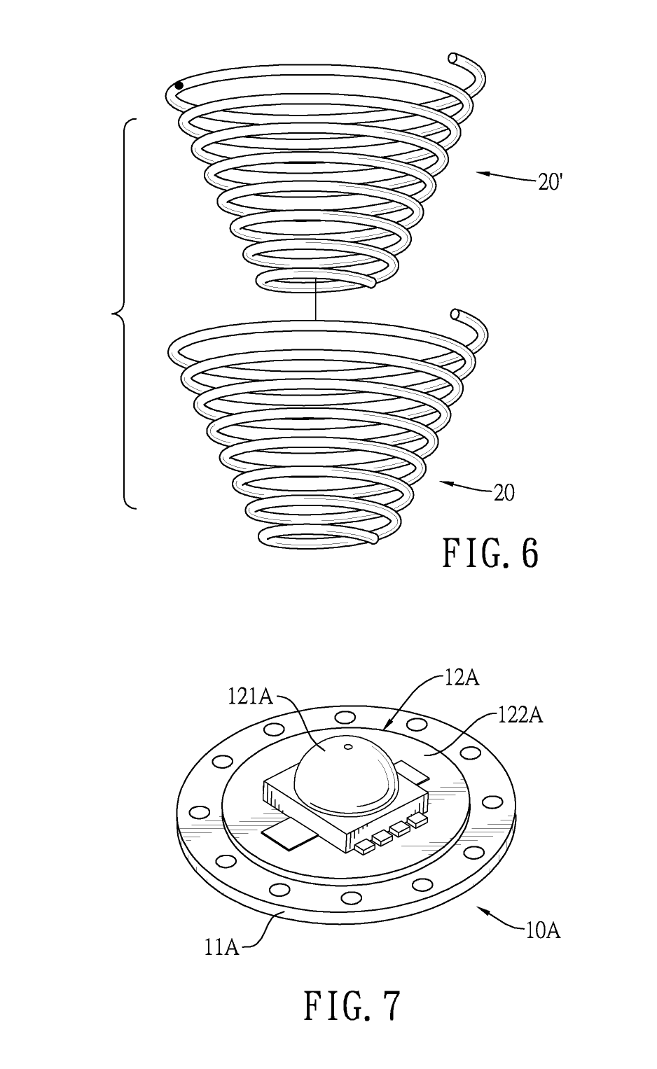

With reference to FIG. 1, each of the at least one heat sink 20 is made of thermally conductive materials and is formed by winding a rod 21 into a tapered helix so as to have a plurality of loops of progressively smaller diameters. The loop of the smallest diameter is mounted to the carrier 11. Two adjacent loops are arranged in spaced relation and do not contact each other. The rod 21 may be wound into a truncated cone. With reference to FIGS. 5 and 6, the lighting device may comprise two heat sinks 20, 20′ connected to each other so as to provide improved heat dissipation.

With reference to FIG. 1, when the lighting device of the invention is in use, the carrier 11 absorbs heat from the heat-generating element 12 and transmits the heat to the heat sink 20 and then the rod 21 radiates the heat to the air. The heat sink 20 can provide improved heat dissipation and air convection because of large surface area of the rod 21 and no dead angle. Furthermore, the heat sink 20 formed by winding a rod 21 is simplified and increases production efficiency as compared to the conventional heat sink formed by metal casting or die casting. Preferably, the heat sink 20 is formed by rod winding with a numerically controlled spring winding machine.

With reference to FIG. 3, in an embodiment, the heat-generating element 12 includes at least one LED mounted on one side surface of the carrier 11. The loop of the smallest diameter of the rod 21 has a distal end affixed to the other side surface of the carrier 11 by using thermally conductive solder 211.

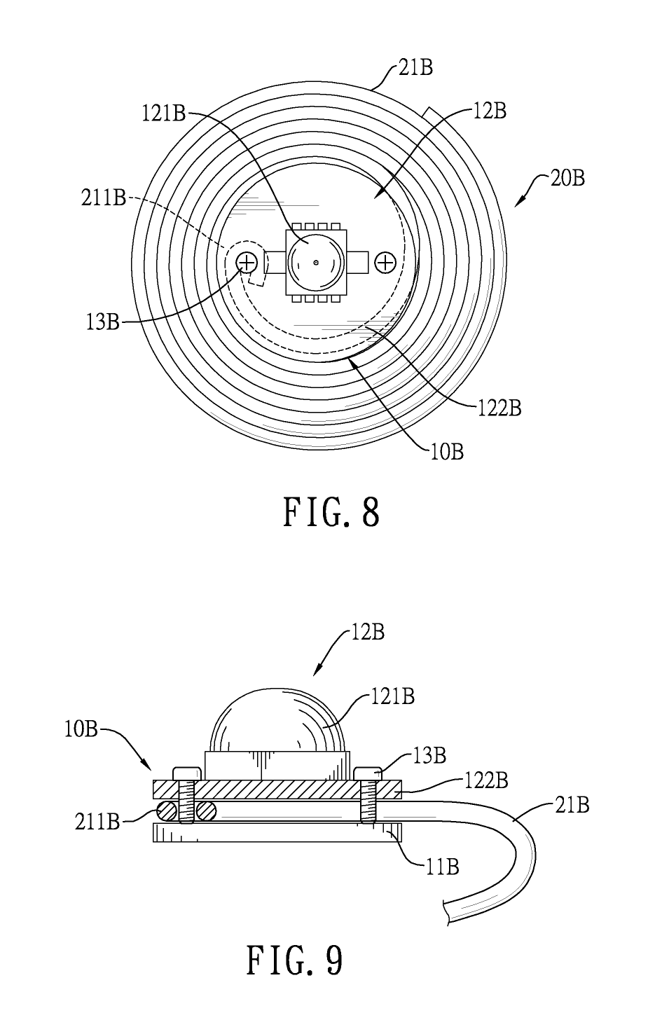

With reference to FIG. 7, in another embodiment, the heat-generating element 12A includes at least one LED 121A mounted on a printed circuit board (PCB) 122A and the PCB 122A is mounted on one side surface of the carrier 11A. With reference to FIGS. 8 and 9, the PCB 122B is secured to the carrier 11B by using thermally conductive screws 13B. The loop of the smallest diameter of the rod 21B is clamped between the PCB 122B and the carrier 11B. A distal end of the loop of the smallest diameter of the rod 21B is bent to form a hook 211B engaging one of the screws 13B.

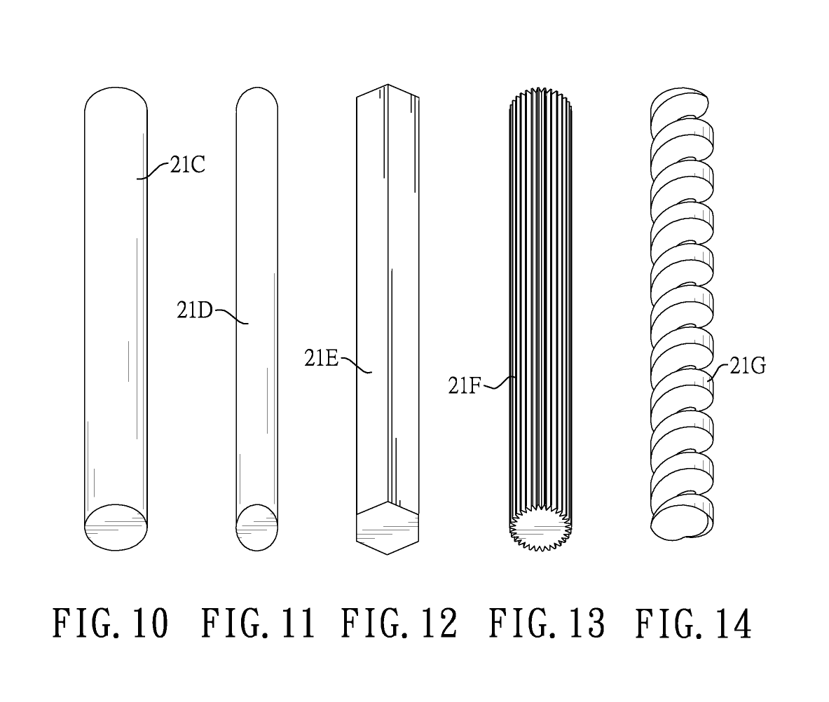

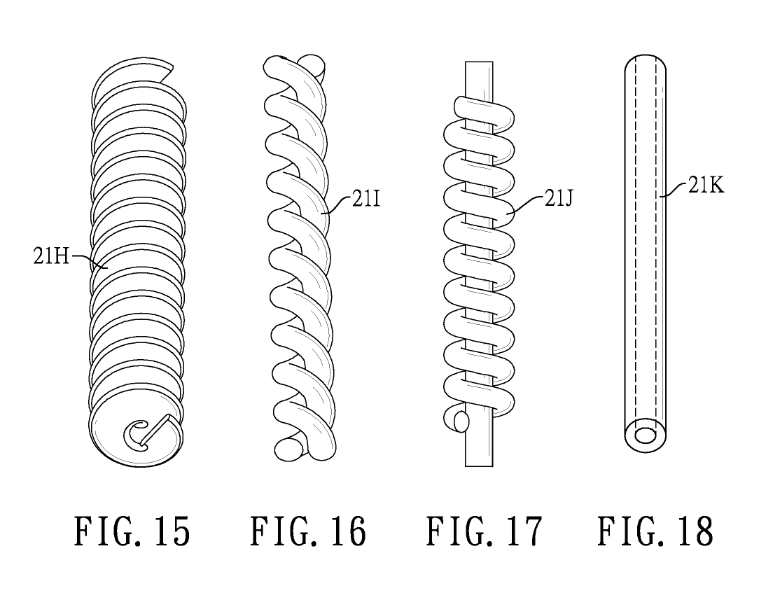

FIGS. 10 to 18 show various embodiments of the rods 21. With reference to FIG. 10, the rod 21C is circular in cross section. With reference to FIG. 11, the rod 21D is oval in cross section. With reference to FIG. 12, the rod 21E is hexagonal in cross section. With reference to FIG. 13, the rod 21F is star-shaped in cross section. With reference to FIG. 14, the rod 21G is formed as a helix. With reference to FIG. 15, the rod 21H is a flat rod formed as a helix. With reference to FIG. 16, the rod 211 is formed as two intertwined helices. With reference to FIG. 17, the rod 21J is formed as a bar being helical along a shaft. With reference to FIG. 18, the rod 21K is made of composite material. Preferably, the rod 21K is a copper rod coated with aluminum.

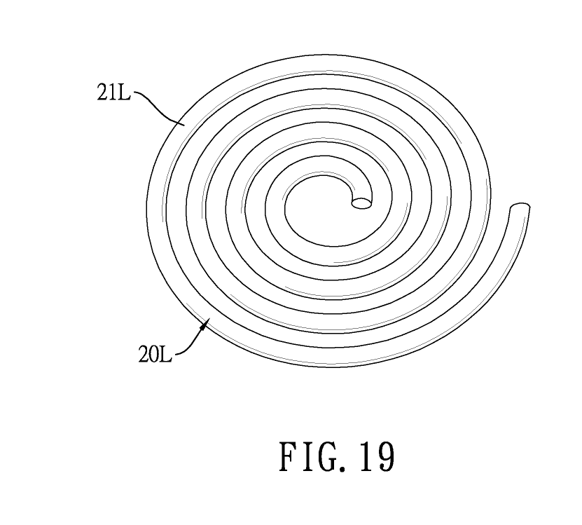

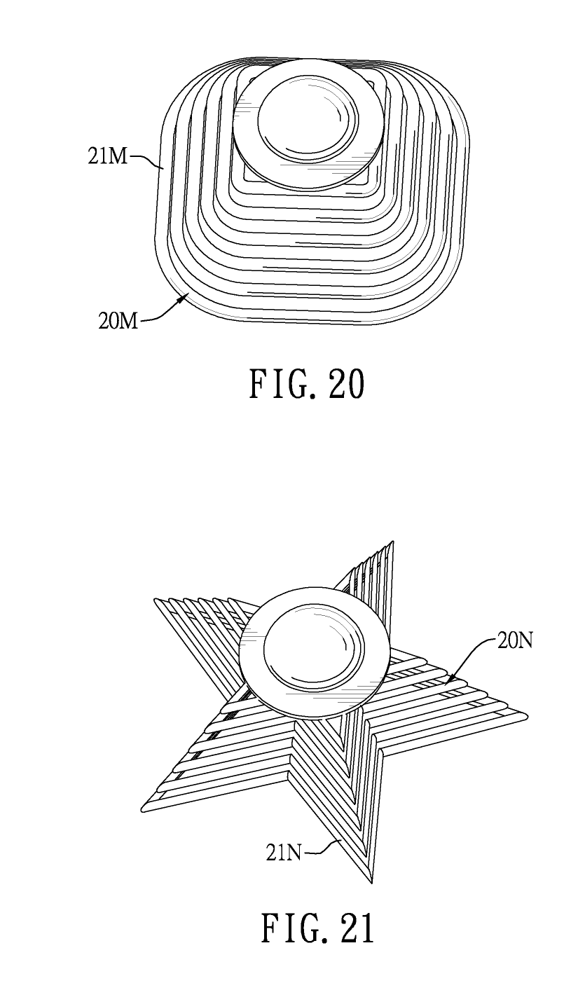

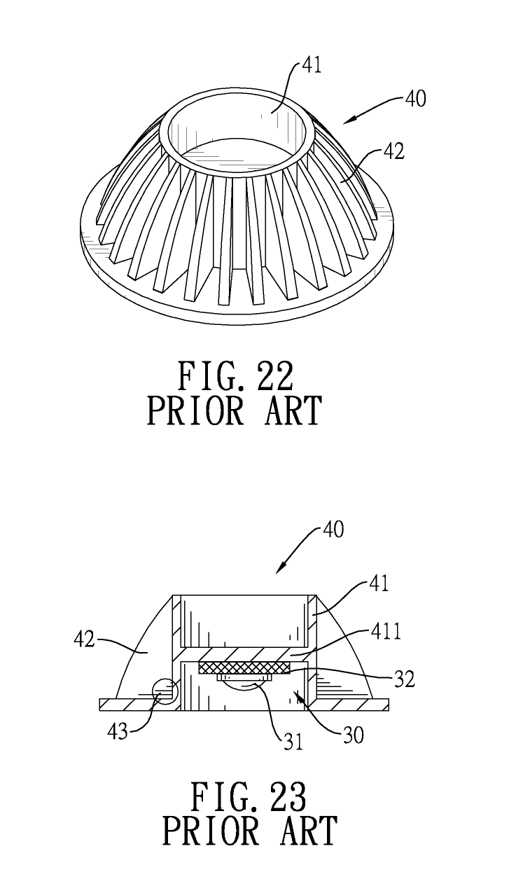

FIGS. 19 to 21 show different configurations of the heat sinks 20 for different installation spaces. With reference to FIG. 19, the heat sink 20L is formed by winding the rod 21L into a spiral. With reference to FIG. 20, the heat sink 20M is formed by winding the rod 21 M into a truncated square pyramid. With reference to FIG. 21, the heat sink 20N is formed by winding the rod 21N into a truncated star pyramid.

Even though numerous characteristics and advantages of the present invention have been set forth in the foregoing description, together with details of the structure and features of the invention, the disclosure is illustrative only. Changes may be made in the details, especially in matters of shape, size and arrangement of parts within the principles of the invention to the full extent indicated by the broad general meaning of the terms in which the appended claims are expressed.

What is claimed is:

1. A heat sink made of thermally conductive materials and formed by winding a rod into a helix so as to have a plurality of loops of progressively smaller diameters.

2. The heat sink as claimed in claim 1, wherein the rod is circular in cross section.

3. The heat sink as claimed in claim 1, wherein the rod is oval in cross section.

4. The heat sink as claimed in claim 1, wherein the rod is hexagonal in cross section.

5. The heat sink as claimed in claim 1, wherein the rod is star-shaped in cross section.

6. The heat sink as claimed in claim 1, wherein the rod is formed as a helix.

7. The heat sink as claimed in claim 1, wherein the rod is a flat rod formed as a helix.

8. The heat sink as claimed in claim 1, wherein the rod is formed as two intertwined helices.

9. The heat sink as claimed in claim 1, wherein the rod is made of composite material.

10. An electronic device comprising:
an electronic component including a heat-generating element mounted on a carrier; and
at least one heat sink and each of the at least one heat sink mounted to the carrier, made of thermally conductive materials and formed by winding a rod into a helix so as to have a plurality of loops of progressively smaller diameters.

11. The electronic device as claimed in claim 10, wherein each loop of the smallest diameter of the rod has a distal end affixed to the carrier by using thermally conductive solder.

12. The electronic device as claimed in claim 10, wherein each of the at least one heat sink is secured to the electronic component by using a thermally conductive screw.

13. The electronic device as claimed in claim 10, wherein the rod is circular in cross section.

14. The electronic device as claimed in claim 10, wherein the rod is oval in cross section.

15. The electronic device as claimed in claim 10, wherein the rod is hexagonal in cross section.

16. The electronic device as claimed in claim 10, wherein the rod is star-shaped in cross section.

17. The electronic device as claimed in claim 10, wherein the rod is formed as a helix.

18. The electronic device as claimed in claim 10, wherein the rod is a flat rod formed as a helix.

19. The electronic device as claimed in claim 10, wherein the rod is formed as two intertwined helices.

20. The electronic device as claimed in claim 10, wherein the rod is made of composite material.
